(19) United States
(12) Patent Application Publication
(10) Pub. No.: US 2016/0003874 A1
(43) Pub. Date: Jan. 7, 2016

(54) MEASURING SYSTEM HAVING SEVERAL SENSORS AND HAVING A CENTRAL EVALUATING UNIT

(71) Applicant: ISABELLENHÜTTE HEUSLER GMBH & CO. KG, Dillenburg (DE)

(72) Inventor: Jan MARIEN, Wiesbaden (DE)

(21) Appl. No.: 14/768,407

(22) PCT Filed: Feb. 25, 2013
(86) PCT No.: PCT/EP2013/000542

§ 371 Date: Aug. 17, 2015

(51) Int. Cl. G01R 15/22; G01R 25/00; G01R 19/02

(52) U.S. Cl. CPC G01R 15/22; G01R 19/02; G01R 25/00

(57) ABSTRACT

The invention relates to a measuring system for measuring electrical measurement variables (I1, I2, I3, U12, U23, U13) in an electrical installation, in particular in a medium voltage installation or in a high voltage installation, including a plurality of sensors (1-3, 8-10) which each measure at least one electrical measurement variable (I1, I2, I3, U12, U23, U13) and output a measurement signal corresponding to the measurement variable (I1, I2, I3, U12, U23, U13), and including a central evaluating unit (7, 14) which receives the measurement signals from the sensors (1-3, 8-10).

The invention relates to a measuring system for measuring electrical measurement variables in an electrical installation, in particular in a medium-voltage installation or in a high-voltage installation.

In the case of such medium-voltage or high-voltage installations, it is known from the prior art to measure specific electrical measurement variables (e.g. current, voltage) by means of sensors which then effect an emergency shut-down e.g. in the event of a fault.

However, such known measuring systems for medium-voltage or high-voltage installations do not provide a comprehensive picture regarding the overall state of the respective medium-voltage or high-voltage installation.

Therefore, the object of the invention is to provide a correspondingly improved measuring system.

This object is achieved by means of an inventive measuring system in accordance with the main claim.

The invention provides a central evaluating unit which receives from the individual sensors in the electrical installation measurement signals which correspond to the electrical measurement variables. The central evaluating unit then evaluates the received measurement signals and thus acquires a comprehensive picture relating to the overall state of the electrical installation being monitored.

In a preferred exemplified embodiment of the invention, at least one of the sensors is at a potential close to high voltage, in particular at a high-voltage potential or at a medium-voltage potential. The term “medium voltage” used within the scope of the invention includes preferably a voltage in the range of 1 kV to 50 kV, whereas the term “high voltage” used within the scope of the invention defines preferably a voltage range of more than 50 kV. In the case of the measuring system in accordance with the invention, the sensors are thus preferably at high voltage or at medium voltage corresponding to the voltage level of the respective electrical installation. In contrast, the central evaluating unit is preferably at a potential close to earth, in particular at an earth potential or a ground potential. In this case, it should be mentioned that the sensor at the potential close to high voltage is preferably galvanically separated from the evaluating unit at the potential close to earth. This galvanic separation between the sensors on the one hand and the central evaluating unit on the other hand is preferably enabled by virtue of the fact that data is transmitted from the sensors to the central evaluating unit via a light conductor, which is known per se from the prior art and therefore does not have to be described in greater detail.

It should also be mentioned that the individual sensors generally require a current supply in order to be able to operate electronic devices contained in the sensors (e.g. an ASIC: Application Specific Integrated Circuit). The measuring system in accordance with the invention thus preferably also comprises at least one current supply unit which supplies current to the sensors, wherein the current supply unit is preferably at a potential close to earth, in particular at a ground potential or an earth potential. In this case, it is important that the current supply unit at the potential close to earth is galvanically separated from the sensors at the potential close to high voltage.

One technical option for implementing this galvanic separation of the current supply unit on the one hand and the sensors on the other hand resides in the fact that the current supply unit is connected to the sensors via a light conductor and transmits the required energy for operating the sensors in the form of light. In this case, the current supply unit contains a light source (e.g. a laser, laser diode, etc.) which generates an intensive light which is transmitted via the light conductor to the individual sensors where the transmitted light is then converted by means of a solar cell into the electrical current required for operating the respective sensor.

Another option for technically implementing the galvanic separation between the current supply unit on the one hand and the sensors on the other hand is to provide a transformer in the current supply unit, said transformer being connected to the individual sensors via a high voltage-insulated cable. In this case, it is important that the insulation capability of the transformer and of the high voltage-insulated cable is sufficient to insulate the voltage level of the sensors with respect to the voltage level of the current supply unit.

In the preferred exemplified embodiment of the invention, at least one of the sensors is a current sensor which measures an electrical current in a current line. Preferably, the current sensor contains for this purpose a low-ohmic current-measuring resistor (“shunt”) which is electrically connected in series in the current line and through which the electrical current to be measured flows. Such low-ohmic shunts are known e.g. from EP 0 605 800 A1 and therefore the content of this patent application regarding the structure and mode of operation of the shunt is to be ascribed in its entirety to the present description. Furthermore, the current sensor preferably contains a measuring circuit which in accordance with the known four-wire technology measures the voltage drop across the shunt and outputs a measurement signal corresponding to the voltage drop, wherein according to Ohm's law this measurement signal is a measurement of the current flowing through the current line. For example, the measuring circuit can be designed as an ASIC (Application Specific Integrated Circuit), as known e.g. from EP 1 363 131 A1, and therefore the content of this patent application is to be ascribed in its entirety to the present description regarding the structure and mode of operation of the measuring circuit. In this case, it should be mentioned that the current sensor is preferably suitable both for direct current and alternating current with different frequency components.

Furthermore, in the case of the measuring system in accordance with the invention preferably one of the sensors is a voltage sensor which measures a voltage of the respective current line. In this case, the voltage sensor can be constructed in the same manner as the above-described current sensor and can measure the voltage across a high-ohmic voltage splitter, which is likewise known per se from the prior art.

In the preferred exemplified embodiment of the invention, at least one of the sensors contains an analogue-to-digital converter which converts an analogue measurement value of the electrical measurement variable into a digital measurement signal which is then transmitted from the sensor to the central evaluating unit. Preferably, the analogue-to-digital converter is a 1-bit-sigma/delta-analogue-to-digital converter, as also known e.g. from EP 1 363 131 A1 as a component of an ASIC.

It should also be mentioned that the central evaluating unit preferably comprises a first digital data interface for communicating with the sensors. Furthermore, for the purpose of outputting data, the central evaluating unit preferably has a second digital data interface, such as e.g. an Ethernet interface, a parallel data interface or serial data interface, such as e.g. an RS485 interface or a CAN-bus interface. The central evaluating unit thus receives from the individual sensors measurement signals corresponding to the respective electrical measurement variables, wherein these measurement signals are then evaluated in the central evaluating unit. In dependence upon the signal evaluation, the central evaluating unit can then output data via the second digital data interface, said data describing the state of the electrical installation.

In this case, it should be mentioned that for communicating with the sensors, the first digital data interface preferably has a substantially greater data transmission rate than the second digital data interface which is provided for outputting data from the central evaluating unit. This is expedient because the measurement is effected by the individual sensors preferably in real time, which requires a correspondingly high data transmission rate between the sensors and the central evaluating unit, whereas the output of data by the central evaluating unit does not have to be effected in real time.

In the preferred exemplified embodiment of the invention, the evaluating unit contains a microprocessor for evaluating the measurement signals received by the sensors, wherein the microprocessor determines from at least one of the measurement variables a derived variable, such as e.g. a root-mean-square value, frequency or harmonic component of the respective measurement variable.

Furthermore, within the scope of the invention the possibility exists that the microprocessor determines a derived variable from the measurement signals of at least two different sensors. If one of the sensors is e.g. a current sensor and the other sensor is a voltage sensor, the microprocessor can determine the phase angle, the effective power or the apparent power from the associated measurement signals of the two sensors.

It has already been briefly mentioned that the galvanic separation between the sensors on the one hand and the central evaluating unit on the other hand can be effected by virtue of the fact that the central evaluating unit is connected to the sensors by means of light conductors. Therefore, the sensors preferably comprise electro-optical converters which convert the electrical measurement variable into the optical measurement signal which is then transmitted via a light conductor to the evaluating unit. The evaluating unit then accordingly comprises an opto-electrical converter which then converts the optical measurement signal into an electrical measurement signal. In this case, a bidirectional data transmission between the central evaluating unit on the one hand and the sensors on the other hand is also possible.

It should also be mentioned that the sensors sample the measurement variable preferably at a sampling frequency of at least 4 kHz, 16 kHz or even at least 40 kHz, in order also to be able to detect a highly dynamic progression of the measurement variable.

In a preferred exemplified embodiment of the invention, the monitored electrical installation comprises a plurality of current lines which can form e.g. a three-phase alternating current network, wherein a neutral conductor can additionally be provided. In this case, preferably each of the current lines is allocated a current sensor which measures the electrical current through the respective current line. In this case, the individual current sensors are preferably connected to a first evaluating unit which monitors the electrical currents through the current lines. Also provided in this case are preferably a plurality of voltage sensors which measure the electrical potential of the individual current lines and in particular preferably in relation to another current line or to the neutral conductor. In this case, the voltage sensors are preferably connected to a second evaluating unit which detects and evaluates the voltages of the individual current lines. One of the evaluating units is thus responsible for monitoring the current in the three-phase alternating current network, whereas the other evaluating unit is responsible for monitoring the voltage.

In the preferred exemplified embodiment, these two evaluating units are connected to one another, e.g. via a synchronisation interface which renders it possible to synchronise the two evaluating units with respect to time and therefore it is possible to measure current on the one hand and voltage on the other hand in each case at the same point in time.

Furthermore, the two evaluating units for monitoring current and voltage can also be connected to one another by means of a data interface, in order to be able to exchange data relating to the measurement signals.

However, the monitored electrical installation does not have to be an installation with a three-phase alternating current network. On the contrary, the invention is also suitable for monitoring an electrical installation with a single-phase alternating current network or a direct current network.

Finally, it should also be mentioned that the measuring system in accordance with the invention preferably has a withstand voltage of at least 1 kV, 5 kV, 10 kV or 20 kV in relation to the electrical voltage of the measurement variables. In this case, the measuring system preferably permits a current measuring range of at least 100 A, 500 A, 1 kA, 5 kA or 10 kA in relation to the maximum value of the electrical current of the measurement variables.

Other advantageous developments of the invention are characterized in the dependent claims or are explained in greater detail hereinafter together with the description of the preferred exemplified embodiments of the invention with reference to the figures. In the figures:

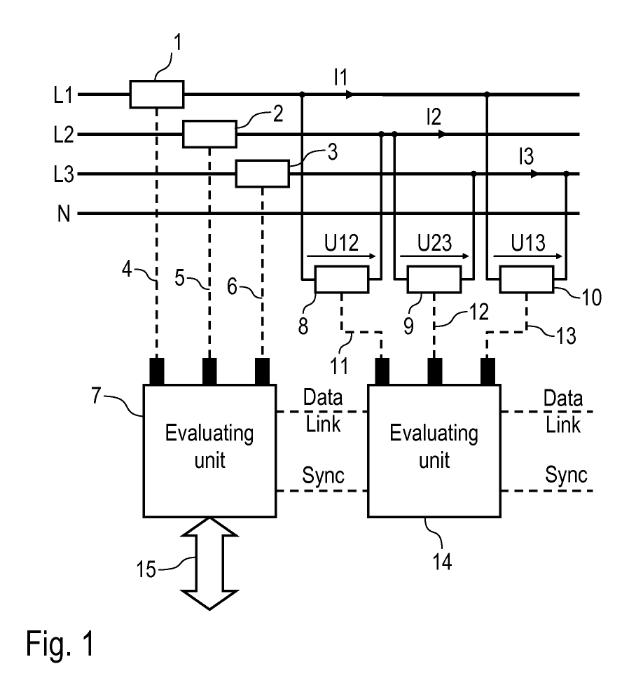

FIG. 1 shows a schematic view of a measuring system in accordance with the invention for an electrical installation having a three-phase alternating current network,

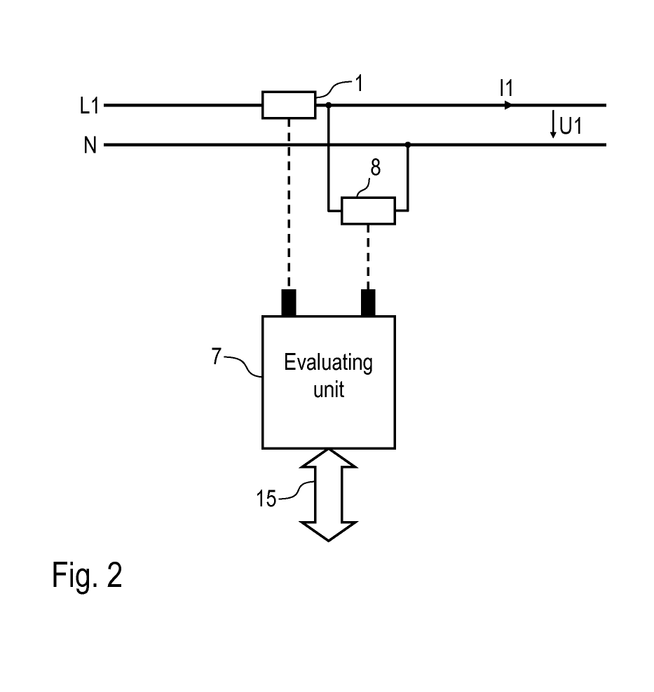

FIG. 2 shows an exemplified embodiment of a measuring system in accordance with the invention for a single-phase alternating current network,

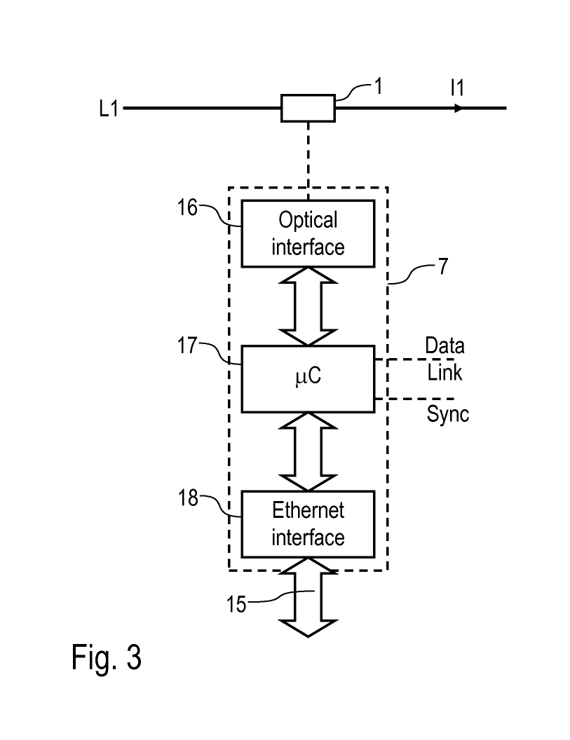

FIG. 3 shows a schematic view of the central evaluating unit of the measuring system in accordance with the invention,

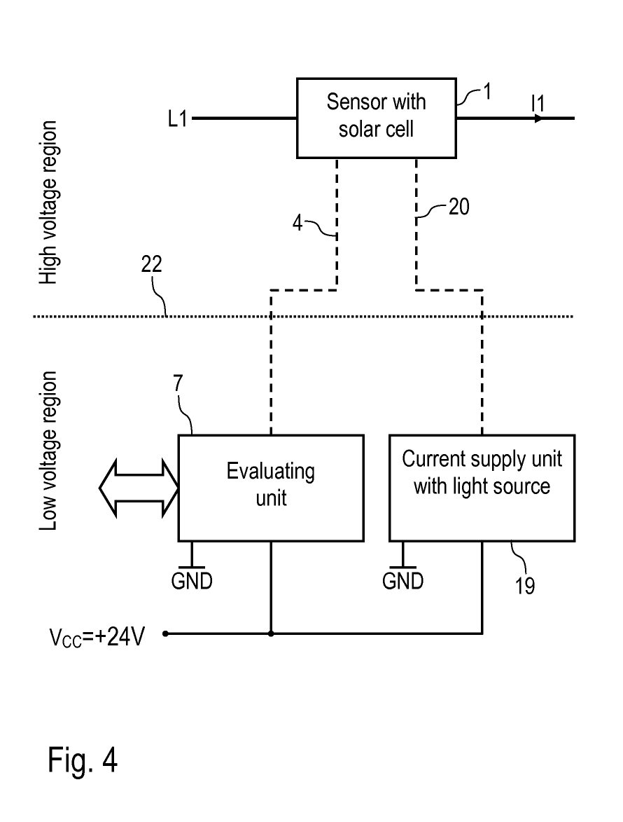

FIG. 4 shows a schematic view to illustrate the current supply to the sensors via light conductors,

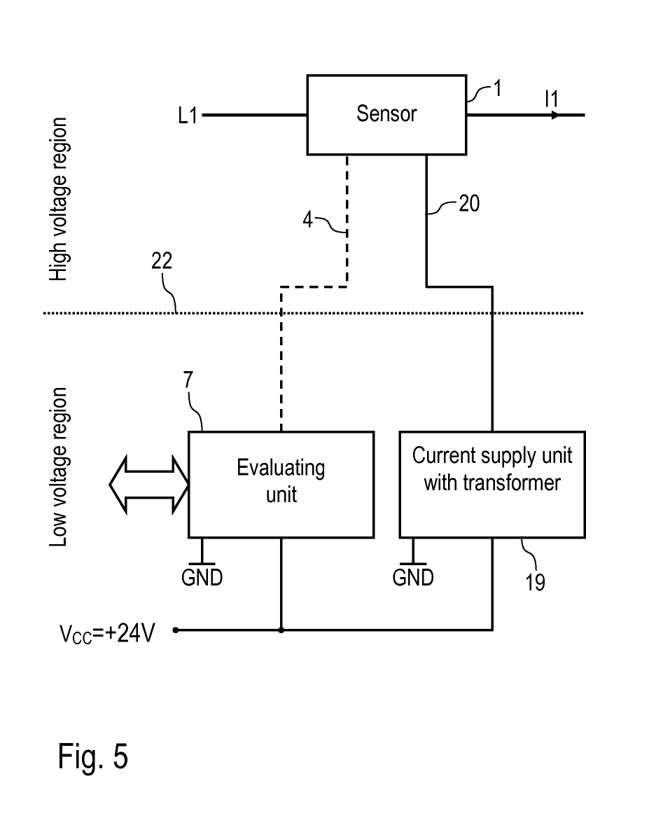

FIG. 5 shows a schematic view to illustrate the current supply to the sensors via a transformer and a high voltage-insulated cable,

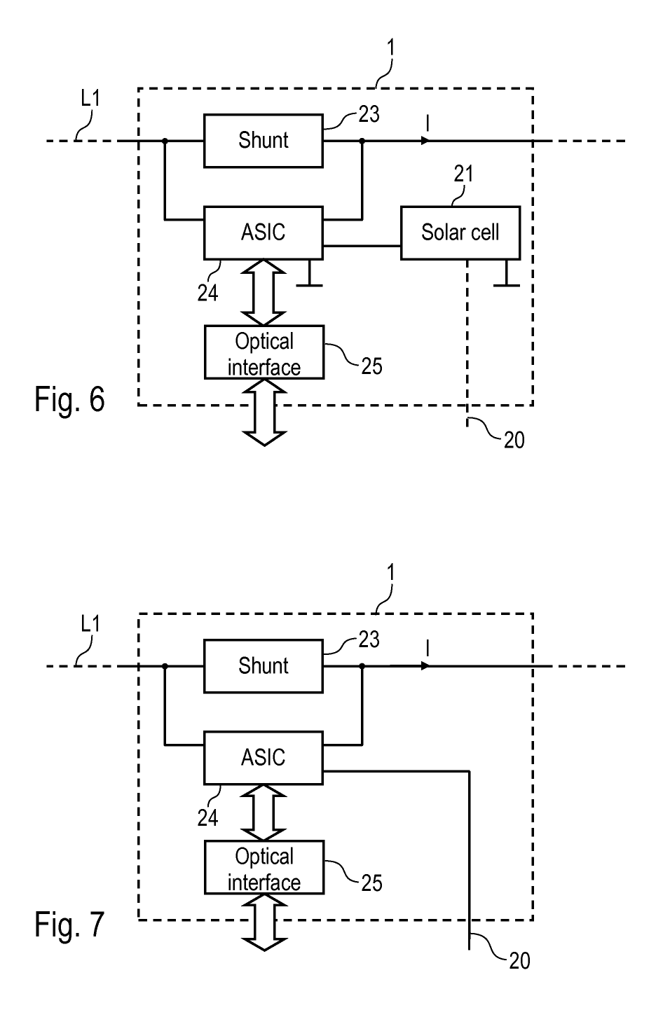

FIG. 6 shows a simplified schematic illustration of a sensor in accordance with the invention having an integrated solar cell for supplying current,

FIG. 7 shows a simplified schematic view of a sensor in accordance with the invention to which current is supplied via a high voltage-insulated cable, and

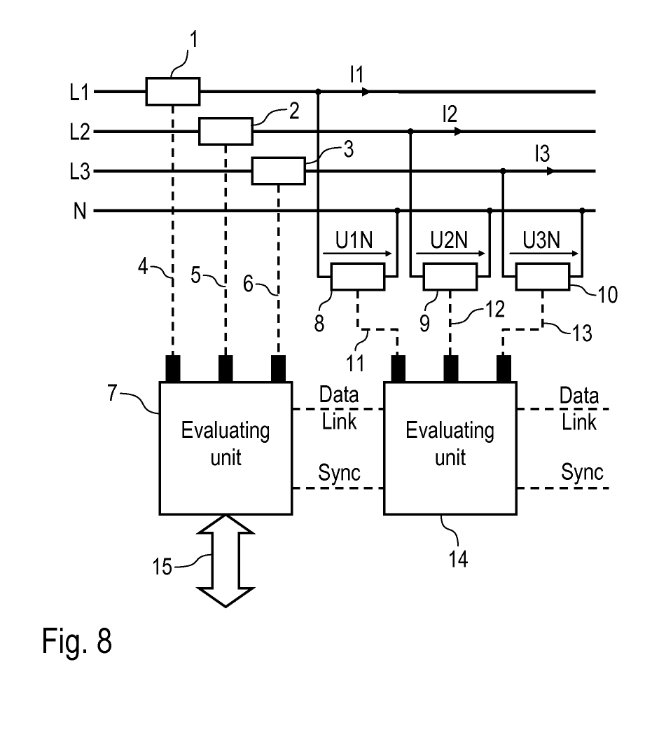

FIG. 8 shows a modification of FIG. 1.

FIG. 1 shows a measuring system in accordance with the invention for measuring electrical currents I1, I2, I3 and electrical voltages U12, U23, U13 in a three-phase alternating current network having three current conductors L1, L2, L3 and a neutral conductor N, wherein such three-phase alternating current networks are known per se from the prior art and therefore do not have to be described in greater detail.

A current sensor 1, 2 and 3 is arranged in each case in the current conductors L1, L2, L3 respectively, in order to measure the electrical currents I1, I2 and I3 in the current conductors L1, L2 and L3 respectively. The structure and the exact mode of operation of the individual current sensors 1-3 will be described in detail hereinafter with reference to FIGS. 6 and 7. At this juncture, it should merely be mentioned that the individual current sensors convert the respectively measured electrical current I1, I2 and I3 into a corresponding measurement signal and transmit same to an evaluating unit 7 via a light conductor 4, 5 and 6 respectively.

Furthermore, the measuring system comprises three voltage sensors 8, 9, 10 which measure the voltages U12, U23 and U13 respectively between the current conductors L1, L2, L3. The structure and the mode of operation of the voltage sensors 8-10 will be described in detail hereinafter. At this juncture, it should merely be mentioned that the voltage sensors 8-10 convert the measured voltage U12, U23 and U13 into a corresponding measurement signal and transmit same to a further evaluating unit 14 via light conductors 11, 12 and 13 respectively.

The evaluating unit 7 thus receives measurement signals of the currents I1, I2 and I3 from the current sensors 1-3 via the light conductors 4-6 respectively, whereas the evaluating unit 14 receives measurement signals of the voltages U12, U23 and U13 from the voltage sensors 8-10 via the light conductors 11-13 respectively.

The two evaluating units 7, 14 are interconnected by means of a synchronisation line SYNC, in order to synchronise the measurements of the two evaluating units 7, 14. This synchronisation via the synchronisation line SYNC ensures that the measurement of the currents I1, I2 and I3 takes place at the same point in time as the measurement of the voltage U12, U23 and U13 respectively. This is important e.g. if variables derived from the currents I1, I2, I3 on the one hand and the voltages U12, U23, U13 on the other hand are to be calculated, such as e.g. phase angle or the apparent power.

Furthermore, the evaluating units 7, 14 are also interconnected to one another via a data connection DATA LINK, in order to be able to interchange the measurement results of the currents I1, I2, I3 and the voltages U12, U23, U13. This is also important if variables derived from the currents I1, I2, I3 on the one hand and the voltages U12, U23, U13 on the other hand are to be calculated.

The evaluating unit 7 can then calculate variables which are derived from the measurement values of the currents I1, I2, I3 and the voltages U12, U23, U13 and which take into account both voltage and current, such as e.g. phase angle between current and voltage on the one hand, effective power or apparent power.

Furthermore, the evaluating unit 7 can calculate variables which are derived from the individual measurement values of the currents I1, I2, I3 and the voltages U12, U23, U13 and which in each case take into account only current or voltage, such as e.g. root-mean-square value, frequency or harmonic component.

These derived variables can then be output by the evaluating unit 7 via a schematically illustrated interface 15. In this case, it should be mentioned that data is transmitted via the light conductors 4-6, 11-13 at a substantially greater data transmission rate than the data transmission rate via the interface 15. This is expedient since a measurement of the currents I1, I2, I3 and the voltages U12, U23, U13 should be performed in real time, which requires a correspondingly high data transmission rate on the light conductors 4-6, 11-13. In contrast thereto, the transmission of the derived variables via the interface 15 imposes substantially lower requirements on the data transmission rate.

FIG. 2 shows a modification of the exemplified embodiment in accordance with FIG. 1, and therefore for the purpose of avoiding repetition reference is made to the description above, wherein the same reference numerals are used for corresponding details.

One particular aspect of this exemplified embodiment is that in this case only one current conductor L1 and one neutral conductor N are present, which embodiment optionally can be a direct voltage network or a single-phase alternating current network.

FIG. 3 schematically shows the structure of the evaluating unit 7 comprising an optical interface 16, a microcomputer 17 and an Ethernet interface 18 for outputting the derived variables by means of the evaluating unit 7.

The optical data transmission between the current sensor 1 and the evaluating unit 7 via the light conductor 4 offers, as also in the case of the other current sensors 2, 3 and the voltage sensors 8-10, the advantage of a galvanic separation of the evaluating units 7 and 14 with respect to the current sensors 1-3 and the voltage sensors 8-10 respectively. This galvanic separation is also necessary because the current sensors 1-3 and the voltage sensors 8-10 are at a high voltage potential, whereas the evaluating units 7, 14 are at a ground potential or at a low voltage potential.

FIG. 4 shows a schematic view to illustrate the current supply to the current sensors 1-3 or the voltage sensors 8-10. By way of example, only the current supply to the current sensor 1 is illustrated in this case, but the current supply to the other current sensors 2, 3 and the voltage sensors 8-10 functions in the same manner.

For instance, the measuring system in accordance with the invention for supplying current comprises a current supply unit 19 which is supplied with current from a voltage supply V_{CC}=+24V. Located in the current supply unit 19 is a strong light source which transmits its light to the current sensor 1 via a light conductor 20. Located in the current sensor 1 is a solar cell 21 (cf. FIG. 6) which converts the light transmitted by the current supply unit 19 via the light conductor 20 into electrical current for supplying current to the current sensor 1.

It is also apparent from this view that the current sensor 1 is located in a high voltage region, whereas the evaluating unit 7 and the current supply unit 19 are located in a low voltage region, wherein the low voltage region is separated from the high voltage region by means of a high voltage insulator 22. The connection between the current sensor 1 in the high voltage region on the one hand and the evaluating unit 7 and the current supply unit 19 in the low voltage region on the other hand is established in this case exclusively via the two light conductors 4, 20, thus effecting a galvanic separation.

FIG. 5 shows a modification of the current supply in accordance with FIG. 4, and therefore for the purpose of avoiding repetition reference is made to the description above, wherein the same reference numerals are used for corresponding details.

One particular aspect of this variant is that the current supply unit 19 does not comprise a light source but rather a transformer, and therefore the current sensor 1 also does not comprise a solar cell. In this case, the transformer in the current supply unit 19 is connected to the current sensor 1 via a high voltage-insulated cable 20. The electric insulation is effected in this case for instance by the insulation of the transformer and by the high voltage-insulated cable 20.

FIG. 6 schematically shows the structure of the current sensor 1, wherein the other current sensors 2, 3 and the voltage sensors 8-10 are constructed in the same manner.

However, the voltage sensors 8-10 measure the voltages U12, U23, U13 in each case via a high-ohmic voltage splitter.

On the one hand, the current sensor 1 contains a low-ohmic current-measuring resistor 23 (“shunt”), as known e.g. from EP 0 605 800 A1.

Furthermore, the current sensor 1 contains an ASIC, as known e.g. from EP 1 363 131 A1. The ASIC 24 measures in accordance with the known four-wire technology the voltage drop across the low-ohmic shunt 23, wherein according to Ohm's law this voltage drop is a measurement of the current I1.

Furthermore, the current sensor 1 in this exemplified embodiment contains the already mentioned solar cell 21 which receives light from the current supply unit 19 via the light conductor, as already described above. The solar cell 21 thus supplies the ASIC 24 with the electrical current required for operation.

Finally, the current sensor 1 also contains an optical interface 25, via which the measurement signals are transmitted from the ASIC 24 to the evaluating unit 7 via the light conductor 4.

FIG. 7 shows a modification of the current sensor 1 of FIG. 6, and therefore for the purpose of avoiding repetition reference is made to the description above, wherein the same reference numerals are used for corresponding details.

One difference in this exemplified embodiment resides in the current supply which in this case is not effected via the solar cell 21 but rather via the high voltage-insulated cable 20.

FIG. 8 shows a modification of the exemplified embodiment in accordance with FIG. 1, and therefore for the purpose of avoiding repetition reference is made to the description above, wherein the same reference numerals are used for corresponding details.

One particular aspect of this exemplified embodiment resides in the fact that the voltage sensors 8-10 each measure the voltage U1N, U2N and U3N between the individual current lines L1, L2 and L3 respectively and the neutral conductor N, whereas in FIG. 1 the voltage U12, U23 and U13 is measured between the individual current lines L1, L2, L3 respectively.

The invention is not limited to the above-described preferred exemplified embodiments. Rather, a multiplicity of variants and modifications are possible which likewise make use of the inventive concept and therefore fall within the scope of protection. In particular, the invention also claims protection for the subject matter and the features of the dependent claims independently of the referenced claims.

### LIST OF REFERENCE NUMERALS

1 current sensor
2 current sensor
3 current sensor
4 light conductor
5 light conductor
6 light conductor
7 evaluating unit
8 voltage sensor
9 voltage sensor
10 voltage sensor
11 light conductor
12 light conductor
13 light conductor
14 evaluating unit
15 interface
16 optical interface
17 microcomputer
18 Ethernet interface
19 current supply unit
20 light conductor or high voltage-insulated cable
21 solar cell
22 high voltage insulator
23 shunt
24 ASIC
25 optical interface
Data Link data transmission line
I1 current
I1 current
I1 current
L1 current conductor
L2 current conductor
L3 current conductor
N neutral conductor
Sync synchronisation line
U12 voltage between the current lines L1 and L2
U13 voltage between the current lines L1 and L3
U23 voltage between the current lines L2 and L3
U1N voltage between current line L1 and neutral conductor N
U2N voltage between current line L2 and neutral conductor N
U3N voltage between current line L3 and neutral conductor N

1-17. (canceled)

18. A measuring system for measuring electrical measurement variables in an electrical installation, comprising:
a) a plurality of sensors each of which measures at least one electrical measurement variable and outputs a measurement signal corresponding to the at least one electrical measurement variable, and
b) a central evaluating unit which receives measurement signals from the sensors.

19. The measuring system as claimed in claim 1, wherein
a) at least one sensor of the plurality of sensors is at a potential close to high voltage,
b) the central evaluating unit is at a potential close to earth, and
c) the at least one sensor at the potential close to high voltage is galvanically separated from the central evaluating unit at the potential close to earth.

20. The measuring system as claimed in claim 19, wherein the central evaluating unit is connected via a light conductor to the at least one sensor at the potential close to high voltage, in order to read out the measurement signal and to separate the central evaluating unit galvanically from the at least one sensor.

21. The measuring system as claimed in claim 19, wherein
a) a current supply unit is provided for supplying current to the at least one sensor at the potential close to high voltage, wherein the current supply unit is connected to the at least one sensor and is at a potential close to earth, and
b) the current supply unit at the potential close to earth is galvanically separated from the at least one sensor at the potential close to high voltage.

22. The measuring system as claimed in claim 21, wherein the current supply unit comprises a galvanically separated transformer which is connected via an electrically insulated cable to the at least one sensor at the potential close to high voltage.

23. The measuring system as claimed in claim 21, wherein
a) the current supply unit comprises a light source,
b) the at least one sensor at the potential close to high voltage comprises a solar cell, in order to generate electrical energy required for operating the at least one sensor, and
c) the light source in the current supply unit is connected via a light conductor to the solar cell in the at least one sensor at the potential close to high voltage.

24. The measuring system as claimed in claim 18, wherein
a) at least one of the sensors is a current sensor which measures an electrical current in a current line,
b) the current sensor contains a low-ohmic shunt which is electrically connected in series in the current line and through which the electrical current to be measured flows, and
c) the current sensor comprises a measuring circuit which measures a voltage drop across the shunt and outputs a measurement signal corresponding to the voltage drop, and
d) the current sensor is suitable for detecting direct currents and also alternating currents with different frequency components.

25. The measuring system as claimed in claim 18, wherein
a) at least one sensor of the plurality of sensors contains an analogue-to-digital converter which converts an analogue measurement value of the at least one electrical measurement variable into a digital measurement signal, and
b) the central evaluating unit comprises a first digital data interface for communicating with the plurality of sensors, and
c) for the purpose of outputting data, the central evaluating unit comprises a second digital data interface, and
d) the first digital data interface has a substantially greater data transmission rate than the second digital data interface.

26. The measuring system as claimed in claim 18, wherein the central evaluating unit comprises a microprocessor for evaluating the measurement signals received from the sensors.

27. The measuring system according to claim 26, wherein the microprocessor determines from at least one of the at least one electrical measurement variable a derived variable.

28. The measuring system according to claim 26, wherein the microprocessor determines from measurement variables of at least two sensors a derived variable.

29. The measuring system according to claim 28, wherein the derived variable is a phase angle between the measurement variables.

30. The measuring system according to claim 28, wherein the derived variable is an effective power, wherein one of the measurement variables is an electrical current, and another measurement variable is an electrical voltage.

31. The measuring system according to claim 28, wherein the derived variable is an apparent power, wherein one of the measurement variables is an electrical current, and another measurement variable is an electrical voltage.

32. The measuring system as claimed in claim 18, wherein
a) at least one sensor of the plurality of sensors comprises an electro-optical converter which converts the measurement variable into the optical measurement signal,
b) the at least one sensor is connected to the central evaluating unit via a light conductor, in order to transmit the optical measurement signal from the at least one sensor to the central evaluating unit, and
c) the central evaluating unit comprises an opto-electrical converter which converts the optical measurement signal into an electrical measurement signal.

33. The measuring system as claimed in claim 18, wherein at least one of the sensors samples the at least one electrical measurement variable at a sampling frequency of at least 4 kHz.

34. The measuring system as claimed in claim 18, wherein at least one of the sensors is a current sensor and at least one of the sensors is a voltage sensor.

35. The measuring system as claimed in claim 18, further comprising:
a) a plurality of current lines in which in each case an electrical current flows and which are each at an electrical potential,
b) a plurality of current sensors which measure the electrical current in one of the current lines respectively,
c) a first evaluating unit which is connected to the current sensors,
d) a plurality of voltage sensors which measure the electrical potential of one of the current lines respectively, and
e) a second evaluating unit which is connected to the voltage sensors.

36. The measuring system as claimed in claim 35, wherein the first and second evaluating units are connected to one another.

37. The measuring system as claimed in claim 36, wherein a connection between the first and second evaluating units is made by a synchronization interface for synchronizing the first and second evaluating units.

38. The measuring system as claimed in claim 36, wherein a connection between the first and second evaluating units is made by a data interface for exchanging data between the first and second evaluating units.

39. The measuring system according to claim 36, wherein one of the first and second evaluating units comprises a second digital data interface for outputting data.

40. The measuring system as claimed in claim 35, wherein
a) the current lines form a three-phase alternating current network, and
b) the voltage sensors each measure a voltage between two of the current lines, or
c) the voltage sensors each measure the voltage between one of the current lines and a neutral conductor.

41. The measuring system as claimed in claim 18, further comprising:
a) a first current line,
b) a second current line,
c) a current sensor which measures an electrical current in the first current line, and
d) a voltage sensor which measures an electrical voltage between the first current line and the second current line,
e) wherein the central evaluating unit is connected to the current sensor and the voltage sensor.

42. The measuring system as claimed in claim 18, further comprising:
a) a withstand voltage of at least 1 kV in relation to the electrical voltage of the at least one electrical measurement variable, and
b) a current measuring range of at least 100 A in relation to a maximum value of an electrical current of the at least one electrical measurement variable.
